(19) United States
(12) Patent Application Publication
(10) Pub. No.: US 2025/0077377 A1
(43) Pub. Date: Mar. 6, 2025

(54) METHOD, APPARATUS, BLOCKCHAIN SERVER AND STORAGE MEDIUM FOR DETERMINING TEMPERATURE OF COOLING LIQUID

(71) Applicant: SHENZHEN MICROBT ELECTRONICS TECHNOLOGY CO., LTD., GUANGDONG (CN)

(72) Inventors: Yang GAO, GUANGDONG (CN); Lihong HUANG, GUANGDONG (CN); Qian CHEN, GUANGDONG (CN); Weibin MA, GUANGDONG (CN); Haifeng GUO, GUANGDONG (CN)

(73) Assignee: SHENZHEN MICROBT ELECTRONICS TECHNOLOGY CO., LTD., GUANGDONG (CN)

(21) Appl. No.: 18/283,874

(22) PCT Filed: Mar. 13, 2023
(86) PCT No.: PCT/CN2023/081053

§ 371 Date: Sep. 25, 2023

(30) Foreign Application Priority Data
Aug. 2, 2022 (CN) 202210918895.1

(51) Int. Cl. G06F 11/30; G06F 1/20; H05K 7/20

(52) U.S. Cl. CPC G06F 11/3058; G06F 1/20; H05K 7/20609; H05K 7/20627; G06F 2200/201

(57) ABSTRACT

A method, an apparatus, a blockchain server and a storage medium for determining a temperature of a cooling liquid are provided. The method includes: determining a first average temperature of a plurality of chips and a first average power of the plurality of chips in a blockchain server, in which the blockchain server includes a liquid cooling system, the liquid cooling system includes a liquid cooling plate and the plurality of chips, the plurality of chips and the liquid cooling plate are in exchange of heat, and the cooling liquid is contained in the liquid cooling plate; determining a thermal resistance coefficient of the liquid cooling system; and determining a first temperature of the cooling liquid based on the first average temperature, the first average power and the thermal resistance coefficient.

### CROSS-REFERENCE TO RELATED APPLICATIONS

This application claims priority to Chinese Patent Application No. 202210918895.1, filed with the China Patent Office on Aug. 2, 2022 and entitled “METHOD AND APPARATUS FOR DETERMINING TEMPERATURE OF COOLING LIQUID, BLOCKCHAIN SERVER AND STORAGE MEDIUM”, which is incorporated herein by reference in its entirety.

### TECHNICAL FIELD

This application belongs to a technical field of information, and particularly relates to a method and an apparatus for determining a temperature of a cooling liquid, a blockchain server and a storage medium.

### BACKGROUND

Generally, blockchain technology is a new distributed infrastructure and a new computing mode that uses a blockchain-type data structure for verifying and storing data, uses a distributed node consensus algorithm for generating and updating the data, uses cryptology for ensuring security of transmission and access of the data, and uses a smart contract including automated script codes for programming and operating the data. A blockchain network is a decentralized network and is a peer-to-peer (P2P) network. A centralized service or a hierarchical structure does not exist in the blockchain network, but instead each node is a peer node, and the individual nodes together provide a network service. A node in the blockchain network is not only a client, but also a server.

At present, with gradual increase of power of a blockchain server, a conventional air-cooling heat dissipation approach may no longer meet its heat dissipation demand, and a liquid-cooling heat dissipation approach is trending. A temperature of the cooling liquid is one of important parameters of the liquid-cooling heat dissipation approach. However, a cooling liquid channel in a liquid cooling plate is closed, so the temperature of the cooling liquid cannot be directly read. If a temperature sensor is additionally arranged in the liquid cooling plate, structural complexity of the liquid cooling plate is increased, and cost is also increased.

### SUMMARY

Embodiments of this application provide a method and an apparatus for determining a temperature of a cooling liquid, a blockchain server and a storage medium.

The technical solutions of embodiments of this application are as follows.

A method for determining a temperature of a cooling liquid comprising:
determining a first average temperature of a plurality of chips and a first average power of the plurality of chips in a blockchain server, wherein the blockchain server comprises a liquid cooling system, the liquid cooling system comprises a liquid cooling plate and the plurality of chips, the plurality of chips and the liquid cooling plate are in exchange of heat, and the cooling liquid is contained in the liquid cooling plate;
determining a thermal resistance coefficient of the liquid cooling system; and determining a first temperature of the cooling liquid based on the first average temperature, the first average power and the thermal resistance coefficient.

An apparatus for determining a temperature of a cooling liquid, comprising:
a first determining module, configured to determine a first average temperature of a plurality of chips and a first average power of the plurality of chips in a blockchain server, wherein the blockchain server comprises a liquid cooling system, the liquid cooling system comprises a liquid cooling plate and the plurality of chips, the plurality of chips and the liquid cooling plate are in exchange of heat, and the cooling liquid is contained in the liquid cooling plate;
a second determining module, configured to determine a thermal resistance coefficient of the liquid cooling system; and
a third determining module, configured to determine a first temperature of the cooling liquid based on the first average temperature, the first average power and the thermal resistance coefficient.

An apparatus for determining a temperature of a cooling liquid includes:
a memory; and
a processor,
wherein the memory stores an application program executable by the processor, to cause the processor to execute the method for determining a temperature of the cooling liquid according to any method described above.

A blockchain server includes:
a liquid cooling plate, containing a cooling liquid;
a chip board, containing a plurality of chips, wherein the chip board and the liquid cooling plate are in exchange of heat; and
a control board, containing a memory and a processor, wherein, the memory stores an application program executable by the processor, to cause the processor to execute the method for determining a temperature of the cooling liquid according to any method described above; and
wherein the chip board has a signal connection with the control board via a signal connection interface, and the chip board has an electrical connection with a power supply via a power supply connection interface.

A computer-readable storage medium storing computer-readable instructions that, when executed by a computer device, execute the method for determining a temperature of the cooling liquid according to any method described above.

In the embodiments of this application, a first average temperature of a plurality of chips and a first average power of the plurality of chips in a blockchain server are determined, in which the blockchain server includes a liquid cooling system, the liquid cooling system includes a liquid cooling plate and the plurality of chips, the plurality of chips and the liquid cooling plate are in exchange of heat, and cooling liquid is contained in the liquid cooling plate. A thermal resistance coefficient of the liquid cooling system is determined. A first temperature of the cooling liquid is determined based on the first average temperature, the first average power and the thermal resistance coefficient. As such, in the embodiments of this application, no temperature sensor is required to be provided in the liquid cooling plate, but instead the temperature of the cooling liquid is determined indirectly by calculating the thermal resistance coefficient of the liquid cooling system containing the liquid cooling plate and the temperature and the power of the chips.

Therefore, costs of deploying the temperature sensor are saved, structural complexity of the liquid cooling plate is reduced, and the implementation is also advantageously convenient.

### BRIEF DESCRIPTION OF THE DRAWINGS

FIG. 1 is an exemplary flowchart of a method for determining a temperature of a cooling liquid in an embodiment of this application.

FIG. 2 is an exemplary schematic top view of a liquid cooling plate in an embodiment of this application.

FIG. 3 is an exemplary schematic sectional view of a liquid cooling plate in an embodiment of this application.

FIG. 4 is a flowchart of an exemplary process of determining a temperature of a cooling liquid in an embodiment of this application.

FIG. 5 is a flowchart of another exemplary process of determining a temperature of a cooling liquid in an embodiment of this application.

FIG. 6 is an exemplary structural diagram of an apparatus for determining a temperature of a cooling liquid in an embodiment of this application.

FIG. 7 is an exemplary structural diagram of another apparatus for determining a temperature of a cooling liquid in an embodiment of this application.

FIG. 8 is an exemplary structural diagram of a blockchain server in an embodiment of this application.

### DETAILED DESCRIPTION

To make objectives, technical solutions, and advantages of this application clearer, this application is described in detail with reference to accompanying drawings.

For concise and intuitive descriptions, solutions of this application are described below by describing several representative embodiments. A large quantity of details in the embodiments are merely for facilitating understanding of the solutions of this application. Apparently, implementation of the technical solutions of this application may not be limited to those details. To avoid unnecessary description making the solutions of this application obscure, some embodiments are not described in detail but are merely outlined. In the following, “include” refers to “include, but is not limited to”, and “according to . . . ” refers to “according to at least . . . ” and is not limited to “according to only . . . ”. Because of conventions of the Chinese language, a component may refer to one or more such components, or may be interpreted as at least one such component, if the quantity of the component is not specifically specified in the following content.

In a blockchain server that adopts a liquid-cooling heat dissipation approach, a strict requirement is imposed for a working condition (especially, a temperature) of a cooling liquid. If the temperature of the cooling liquid cannot be accurately determined, there exists potential hazards in a security strategy, which, for example, may affect safe operations of the blockchain server. At present, in order to determine the temperature of the cooling liquid, those skilled in the art conventionally arrange an additional temperature sensor in a liquid cooling plate. However, a structure of the liquid cooling plate is already complicated. Arranging the additional temperature sensor in the liquid cooling plate will surely increase the structural complexity and also cost.

In the embodiments of this application, the conventional idea that additionally arranges the temperature sensor in the liquid cooling plate to directly measure the temperature of the cooling liquid is changed. The temperature sensor is not to be arranged in the liquid cooling plate. Instead, the temperature of the cooling liquid is inferred indirectly by calculating a thermal resistance coefficient of a liquid cooling system containing the liquid cooling plate and combining temperatures and power values of the chips. Therefore, various defects of deploying the temperature sensor are overcome.

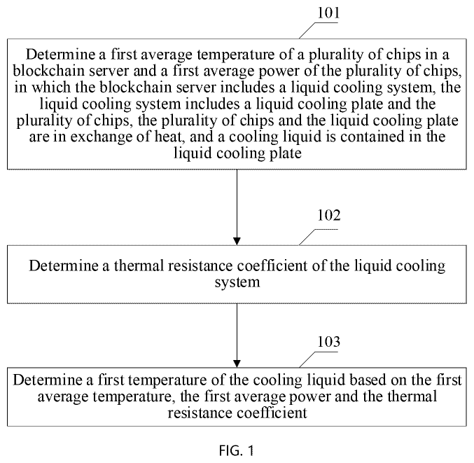

FIG. 1 is an exemplary flowchart of a method for determining a temperature of a cooling liquid in an embodiment of this application.

As shown in FIG. 1, the method for determining the temperature of the cooling liquid includes steps 101-103.

Step 101: a first average temperature of a plurality of chips and a first average power of the plurality of chips in a blockchain server are determined, in which the blockchain server includes a liquid cooling system, the liquid cooling system includes a liquid cooling plate and the plurality of chips, the plurality of chips and the liquid cooling plate are in exchange of heat, and the cooling liquid is contained in the liquid cooling plate.

The blockchain server usually includes a chip board (for example, a computing board). The chip board includes the plurality of chips. For example, the chips are implemented as computing chips for executing blockchain computing. The blockchain server further includes the liquid cooling system for dissipating heat of the plurality of chips. The liquid cooling system may include the liquid cooling plate and the plurality of chips for which heat dissipation is performed. The cooling liquid is contained in the liquid cooling plate. The cooling liquid in the liquid cooling plate, serving as a coolant, is used for transferring heat energy and is a working fluid that generates a cooling effect. The liquid cooling plate may be in direct contact with the plurality of chips, so that heat generated by the plurality of chips during working is transferred through the cooling liquid. For example, the cooling liquid may be implemented as an electronic fluoride fluid, such as a DA-series fluoride fluid and the like.

In an embodiment, a temperature value of each chip is collected, and averaging calculation is performed to determine the first average temperature of the plurality of chips. A total power value of the plurality of chips is collected and then is divided by the number of chips to obtain the first average power. In an embodiment, the first average temperature and the first average power are both real-time values at the current moment.

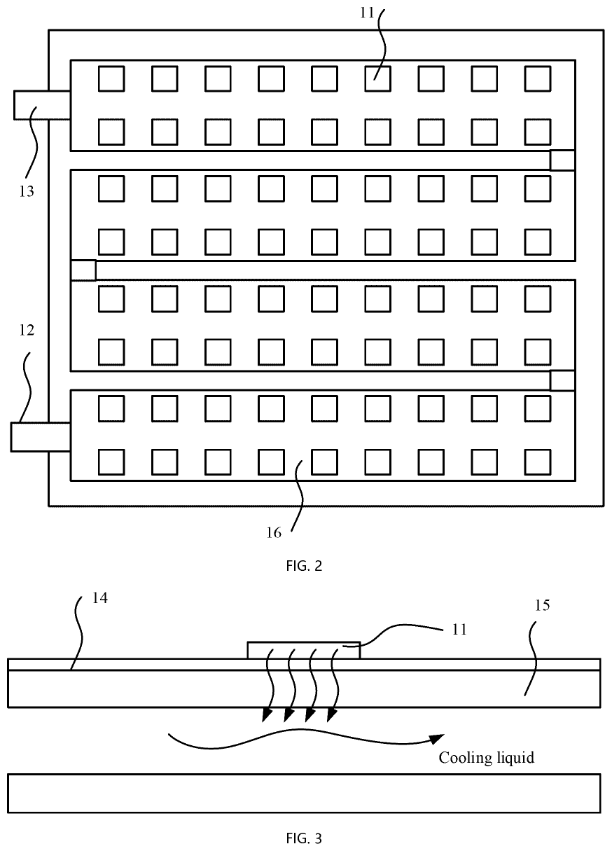

FIG. 2 is an exemplary schematic top view of a liquid cooling plate in an embodiment of this application. FIG. 3 is an exemplary schematic sectional view of a liquid cooling plate in an embodiment of this application.

It may be seen from FIG. 2 and FIG. 3 that the plurality of computing chips 11 form a multi-layer group of computing chips that are connected in series. The computing chips 11 and the liquid cooling plate 16 are in exchange of heat. The cooling liquid flows in the liquid cooling plate 16. The liquid cooling plate 16 includes an inlet 12 for allowing the cooling liquid to enter the liquid cooling plate 16 and an outlet 13 for allowing the cooling liquid to exit the liquid cooling plate 16. The computing chips 11 may be arranged on a printed circuit board 14, so that the computing chips 11 and the printed circuit board 14 together form the chip board. The chip board may be in direct contact with the liquid cooling plate 16 so as to facilitate heat dissipation of the computing chips 11. The cooling liquid flows in a cavity formed by a wall 15 of the liquid cooling plate 16 so as to take away heat that is generated by the computing chips 11 in the chip board during working.

The above description is made by taking a specific structure of the computing chips connected in series and the liquid cooling plate as an example. A person skilled in the art may understand that such description is only exemplary and is not intended to limit the protection scope of the embodiments of this application.

Step 102: a thermal resistance coefficient of the liquid cooling system is determined.

Here, the thermal resistance coefficient of the liquid cooling system is equivalent to a sum of thermal resistances from a heat source (chips) to a whole liquid passageway of the cooling liquid.

The thermal resistance coefficient of the liquid cooling system may be deemed as an inherent physical property of the liquid cooling system, whose value will not change if constitution of the liquid cooling system is not changed.

For example, in a condition that the chips are arranged on the printed circuit board and the printed circuit board is connected with the liquid cooling plate via a thermal-conduction medium (a thermal-conduction paste, a thermal-conduction pad or the like), the thermal resistance coefficient of the liquid cooling system is determined based on a thermal-conduction resistance from a heat source junction (such as a “DIE” of each chip, also called a “bare chip”, which is a structure that remains after removing encapsulation of the chip) of the chip to the circuit board, a thermal-conduction resistance of the printed circuit board, a thermal-conduction resistance of the thermal-conduction medium, a thermal-conduction resistance of the liquid cooling plate, and a heat exchange coefficient between the liquid cooling plate and a liquid medium.

For another example, in a condition that the chips are arranged on the printed circuit board and the printed circuit board is directly connected with the liquid cooling plate, the thermal resistance coefficient of the liquid cooling system is determined based on the thermal-conduction resistance from the heat source junction of each chip to the circuit board, the thermal-conduction resistance of the printed circuit board, the thermal-conduction resistance of the liquid cooling plate, and the heat exchange coefficient between the liquid cooling plate and the liquid medium.

For yet another example, in a condition that the chips are arranged on the printed circuit board, but tops of the chips are connected with the liquid cooling plate via the thermal-conduction medium (the thermal-conduction paste, the thermal-conduction pad or the like), the thermal resistance coefficient of the liquid cooling system is determined based on a thermal-conduction resistance from the heat source junction of each chip to the thermal-conduction medium, the thermal-conduction resistance of the thermal-conduction medium, the thermal-conduction resistance of the liquid cooling plate, and the heat exchange coefficient between the liquid cooling plate and the liquid medium.

In an embodiment, determining the thermal resistance coefficient of the liquid cooling system in step 102 includes: reading the thermal resistance coefficient of the liquid cooling system from a non-volatile memory of the blockchain server or a cloud storage device. In this embodiment, the thermal resistance coefficient of the liquid cooling system is pre-determined and is stored in the non-volatile memory of the blockchain server or the cloud storage device. When the thermal resistance coefficient is needed for calculating the temperature (such as a temperature of the cooling liquid at a current moment) of the cooling liquid, the thermal resistance coefficient is read from the non-volatile memory of the blockchain server or the cloud storage device and is then used to calculate the temperature of the cooling liquid. As such, a step of calculating the thermal resistance coefficient is omitted.

In an embodiment, given that the temperature of the cooling liquid is usually known and stable (such as 35 degrees; a working condition of ex-factory aging is preset according to an aging requirement, which is stable and is provided by a liquid-cooling heat dissipation system) at the time when production and assembling of the blockchain server are completed and its ex-factory aging test is executed, the thermal resistance coefficient of the liquid cooling system may be pre-determined in the ex-factory aging test. In the ex-factory aging test, when the blockchain server has been powered on and its power has reached a pre-determined working condition (such as a rated working condition), the thermal resistance coefficient is calculated based on a combination of an average chip power, an average chip temperature and a temperature of the cooling liquid at the moment. The thermal resistance coefficient=(the average chip temperature−the temperature of the cooling liquid)/the average chip power. The calculated thermal resistance coefficient is stored in a local storage medium (such as a non-volatile memory) of the blockchain server or in a cloud storage medium that the blockchain server has access to. Afterwards, during subsequent use of the blockchain server, the temperature of the cooling liquid may be determined quickly based on a current average chip temperature, a current average chip power and a thermal resistance coefficient that is read from the storage medium.

In an embodiment, a process for pre-determining the thermal resistance coefficient of the liquid cooling system specifically includes: determining a second average temperature of the plurality of chips and a second average power of the plurality of chips in a condition that the blockchain server has reached a pre-determined working condition in the ex-factory aging test of the blockchain server; determining, based on a reading of a temperature sensor of a liquid supply system for providing the cooling liquid for the blockchain server in the ex-factory aging test, a second temperature of the cooling liquid in the condition that the blockchain server has reached the pre-determined working condition; determining the thermal resistance coefficient based on the second average temperature, the second average power and the second temperature; and storing the thermal resistance coefficient into the non-volatile memory of the blockchain server or the cloud storage device. A specific approach of determining the thermal resistance coefficient based on the second average temperature, the second average power and the second temperature includes: the thermal resistance coefficient=(the second average temperature−the second temperature)/the second average power.

For example, it is assumed that in the ex-factory aging test, the temperature of the cooling liquid that was collected by the temperature sensor of the liquid supply system is 35 degrees (° C.). After an operating power of the blockchain server for starting up reaches a stable power, a total power of all the chips at the moment is 7 kw, and an average temperature of all the chips is 80 degrees. It is assumed that the blockchain server has a total of 460 chips. As such, an average power of the chips is 7000/460=15.2 W, and thus the calculated thermal resistance coefficient is: (80−35)/15.2=2.96(° C./W). The thermal resistance coefficient is then stored in the non-volatile memory of the blockchain server or the cloud storage device, so that a current temperature of the cooling liquid is conveniently calculated subsequently by using the read thermal resistance coefficient.

When a property of the liquid cooling system changes (for example, an assembly structure of the circuit board changes, a thickness of the thermal-conduction medium changes, a structure of the liquid cooling plate changes, a property of the cooling liquid changes, or the like), the thermal resistance coefficient of the liquid cooling system will change. In this case, reading the pre-calculated thermal resistance coefficient directly from the storage medium will lead to a calculation error. Therefore, the thermal resistance coefficient needs to be recalibrated if the property of the liquid cooling system changes (for example, if the server is disassembled).

Besides, even though the property of the liquid cooling system does not change, if the pre-calculated thermal resistance coefficient cannot be read from the storage medium based on a certain reason (for example, a communication link accessing the storage medium has been cut off), the thermal resistance coefficient may be voluntarily calculated.

In the condition that the property of the liquid cooling system changes or the pre-calculated thermal resistance coefficient cannot be read from the storage medium, the temperature of the cooling liquid can hardly be read directly to calculate the thermal resistance coefficient, which is unlike the stage of the ex-factory aging test. The applicant discovers that: in subsequent use of the server after the stage of the ex-factory aging test, in a condition that the server has been powered on and the chip board is not started, a temperature of the chip board is approximately the same as the temperature of the cooling liquid. Therefore, the temperature of the chip board at that moment may be used to approximate the temperature of the cooling liquid, which is basically the same, thereby completing calculation of the thermal resistance coefficient.

In an embodiment, determining the thermal resistance coefficient of the liquid cooling system includes: obtaining the temperature of the chip board in a condition that the blockchain server has been powered on and the chip board containing the plurality of chips is not started; starting the chip board; determining a third average temperature of the plurality of chips and a third average power of the plurality of chips in a condition that a power of the blockchain server has reached a pre-determined threshold value for a preset period; determining the thermal resistance coefficient of the liquid cooling system based on the third average temperature, the third average power and the temperature of the chip board (which is the temperature of the chip board that is not started). For example, the thermal resistance coefficient=(the third average temperature−the temperature of the chip board)/the third average power.

For example, after a system has been powered on, in a condition that a control board (which is a circuit board used for controlling the blockchain server to run) of the blockchain server has been powered on and the chip board is not started, the temperature of the chip board is read through a temperature sensor of the chip board at the moment, which is, for example, 40 degrees. The temperature of the cooling liquid at the moment may be considered as 40 degrees. Afterwards, the chip board is started. In a condition that a main power of the chip board has reached 5 kw for about 20 seconds, a temperature of each chip is read. An average temperature value of all the chips is calculated as 70 degrees, and an average power of all the chips is calculated as 5 kW/460=10.87 W. As such, the thermal resistance coefficient is (70−40)/10.87=2.76(° C./W).The thermal resistance coefficient then may be used to determine a current temperature of the cooling liquid at any subsequent moment. In an embodiment, the calculated thermal resistance coefficient is stored in the non-volatile memory of the blockchain server or the cloud storage device, for subsequent direct use.

Step 103: a first temperature of the cooling liquid is determined based on the first average temperature, the first average power and the thermal resistance coefficient.

In an embodiment, step 103 specifically includes: determining T₂, where T₂=T₁−K*P; T₁ is the first average temperature; T₂ is the first temperature; K is the thermal resistance coefficient; and P is the first average power. In an embodiment, the first average temperature and the first average power are real-time values for the blockchain server during working respectively, so that the calculated first temperature is also a real-time value for the cooling liquid.

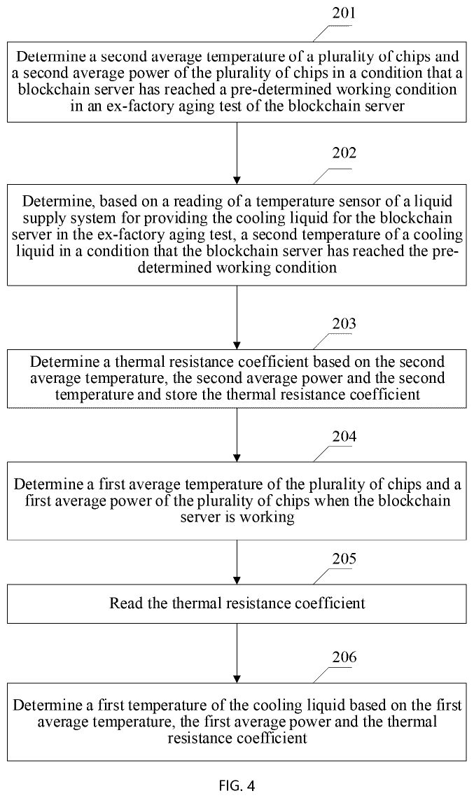

FIG. 4 is a flowchart of an exemplary process of determining a temperature of a cooling liquid in an embodiment of this application.

As shown in FIG. 4, the process of determining the temperature of the cooling liquid includes steps 201-206.

Step 201: a second average temperature of a plurality of chips and a second average power of the plurality of chips are determined in a condition that the blockchain server has reached a pre-determined working condition in the ex-factory aging test of the blockchain server.

Step 202: a second temperature of the cooling liquid in a condition that the blockchain server has reached the pre-determined working condition is determined based on a reading of a temperature sensor of a liquid supply system for providing the cooling liquid for the blockchain server in the ex-factory aging test.

Step 203: the thermal resistance coefficient is determined based on the second average temperature, the second average power and the second temperature, and is stored. For example, the thermal resistance coefficient=(the second average temperature−the second temperature)/the second average power. The thermal resistance coefficient is stored in the local storage medium of the blockchain server or the cloud storage medium.

In step 201 to step 203, the pre-calculation and storage process of the thermal resistance coefficient are completed. In subsequent step 204 to step 206, a real-time temperature of the cooling liquid may be calculated directly by using the thermal resistance coefficient.

Step 204: the first average temperature of the plurality of chips and the first average power of the plurality of chips are determined when the blockchain server is working. For example, the first average temperature and the first average power are respectively real-time values of the blockchain server during working.

Step 205: the thermal resistance coefficient is read. Here, the thermal resistance coefficient may be read from the local storage medium of the blockchain server or the cloud storage medium.

Step 206: the first temperature of the cooling liquid is determined based on the first average temperature, the first average power and the thermal resistance coefficient that is read in step 205.

For example, T₂ is determined, where T₂=T₁−K*P; T₁ is the first average temperature; T₂ is the first temperature; K is the thermal resistance coefficient; and P is the first average power. Here, if the first average temperature and the first average power are real-time values of the blockchain server during working, the first temperature is the real-time temperature of the cooling liquid.

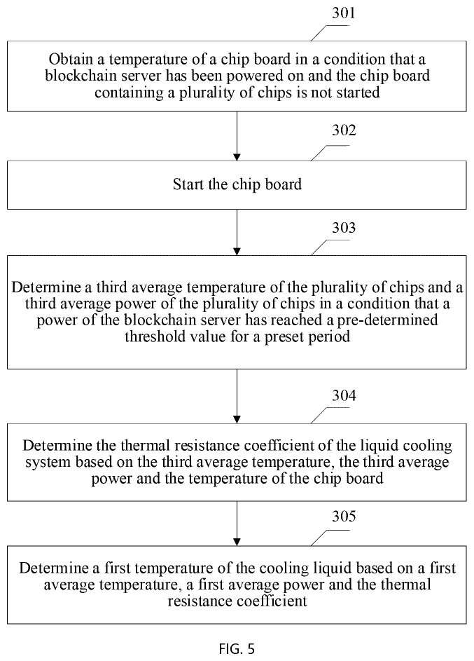

FIG. 5 is a flowchart of another exemplary process of determining a temperature of a cooling liquid in an embodiment of this application.

As shown in FIG. 5, the process of determining the temperature of the cooling liquid includes steps 301-305.

Step 301: a temperature of the chip board is obtained in a condition that the blockchain server has been powered on and the chip board containing the plurality of chips is not started.

Step 302: the chip board is started.

Step 303: a third average temperature of the plurality of chips and a third average power of the plurality of chips are determined in a condition that a power of the blockchain server has reached a pre-determined threshold value for a preset period.

Step 304: the thermal resistance coefficient of the liquid cooling system is determined based on the third average temperature, the third average power and the temperature (namely, the temperature of the chip board that is not started) of the chip board. Here, the temperature of the chip board is used to approximate the temperature of the cooling liquid, which is basically the same. The thermal resistance coefficient=(the third average temperature−the temperature of the chip board)/the third average power.

Step 305: the first temperature of the cooling liquid is determined based on the first average temperature, the first average power and the thermal resistance coefficient calculated in step 304.

For example, T₂ is determined, where T₂=T₁−K*P; T₁ is the first average temperature; T₂ is the first temperature; K is the thermal resistance coefficient calculated in step 304; and P is the first average power. Here, if the first average temperature and the first average power are the real-time values of the blockchain server during working, the first temperature is the real-time temperature of the cooling liquid.

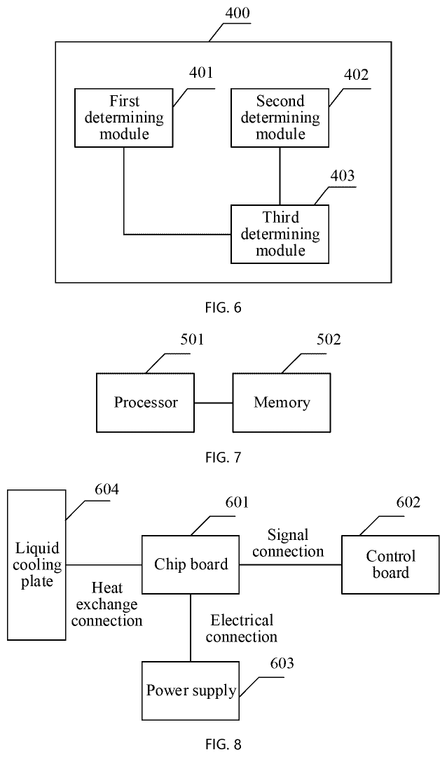

FIG. 6 is an exemplary structural diagram of an apparatus for determining a temperature of a cooling liquid in an embodiment of this application.

As shown in FIG. 6, an apparatus 400 for determining the temperature of the cooling liquid includes:
a first determining module 401, configured to determine a first average temperature of a plurality of chips and a first average power of the plurality of chips in a blockchain server, in which the blockchain server includes a liquid cooling system, the liquid cooling system includes a liquid cooling plate and the plurality of chips, the plurality of chips and the liquid cooling plate are in exchange of heat, and the cooling liquid is contained in the liquid cooling plate;
a second determining module 402, configured to determine a thermal resistance coefficient of the liquid cooling system; and
a third determining module 403, configured to determine a first temperature of the cooling liquid based on the first average temperature, the first average power and the thermal resistance coefficient.

In an exemplary embodiment, the second determining module 402 is configured to read the thermal resistance coefficient of the liquid cooling system from a non-volatile memory of the blockchain server or a cloud storage device.

In an exemplary embodiment, the second determining module 402 is configured to determine a second average temperature of the plurality of chips and second average power of the plurality of chips in a condition that the blockchain server has reached a pre-determined working condition in an ex-factory aging test of the blockchain server; determine, based on a reading of a temperature sensor of a liquid supply system for providing the cooling liquid for the blockchain server in the ex-factory aging test, a second temperature of the cooling liquid in a condition that the blockchain server has reached the pre-determined working condition; determine the thermal resistance coefficient based on the second average temperature, the second average power and the second temperature; and store the thermal resistance coefficient into the non-volatile memory of the blockchain server or the cloud storage device.

In an exemplary embodiment, the second determining module 402 is configured to obtain a temperature of a chip board in a condition that the blockchain server has been powered on and the chip board containing the plurality of chips is not started; start the chip board; determine a third average temperature of the plurality of chips and third average power of the plurality of chips in a condition that power of the blockchain server has reached a pre-determined threshold value for a preset period; and determine the thermal resistance coefficient of the liquid cooling system based on the third average temperature, the third average power and the temperature (namely, the temperature of the chip board which is not started) of the chip board.

In an exemplary embodiment, the third determining module 403 is configured to determine T₂, where T₂=T₁−K*P; T₁ is the first average temperature; T₂ is the first temperature; K is the thermal resistance coefficient; and P is the first average power.

FIG. 7 is an exemplary structural diagram of another apparatus for determining a temperature of a cooling liquid in an embodiment of this application.

As shown in FIG. 7, the apparatus for determining the temperature of the cooling liquid includes: a processor 501 and a memory 502. The memory 502 stores an application program executable by the processor 501, to cause the processor 501 to execute the method(s) for determining the temperature of the cooling liquid according to any one of above embodiments. The memory 502 may be specifically implemented as various storage media, such as an electrically erasable programmable read-only memory (EEPROM), a flash memory and a programmable read-only memory (PROM). The processor 501 may be implemented to include one or more central processing units or one or more field-programmable gate arrays, in which the field-programmable gate array is integrated with one or more central processing unit cores. Specifically, the central processing unit or the central processing unit core may be implemented as a CPU, an MCU, or a digital signal processor (DSP).

An embodiment of this application further provides a blockchain server. FIG. 8 is an exemplary structural diagram of a blockchain server in an embodiment of this application. As shown in FIG. 8, the blockchain server includes:
a liquid cooling plate 604, containing a cooling liquid;
a chip board 601, exchanging heat with the liquid cooling plate 604 (for example, the liquid cooling plate 604 is in direct contact with the chip board 601 or is in contact with the chip board via a thermal-conduction medium so as to exchange heat); and
a control board 602, containing a memory and a processor. The memory stores an application program executable by the processor, to cause the processor to execute the method(s) for determining the temperature of the cooling liquid according to any one of above embodiments. The chip board 601 forms a signal connection with the control board 602 through a signal connection interface, and the chip board 601 forms an electrical connection with a power supply 603 through a power supply connection interface.

It should be noted that not all steps and modules in all the above flows and structural diagrams are necessary, and some steps or modules may be omitted according to actual needs. An execution sequence of all the steps is not fixed and may be adjusted according to needs. All the modules are functionally divided merely for convenience of description. In actual implementations, one module may be implemented by a plurality of modules, or functions of multiple modules may alternatively be implemented by one module. These modules may be located in the same device or in different devices. Hardware modules in all the embodiments may be implemented in a mechanical manner or an electronic manner. For example, a hardware module may include a specially designed permanent circuit or logic device (for example, an application-specific processor such as an FPGA or an ASIC) to complete specific operations. The hardware module may also include a programmable logic device or circuit (for example, including a general-purpose processor or other programmable processors) temporarily configured by software to execute specific operations. Whether the hardware module is specifically implemented by using the mechanical manner, using the application-specific permanent circuit, or using the temporarily configured circuit (for example, being configured by software) may be determined in consideration of cost and time.

An embodiment of this application further provides a computer-readable storage medium, which stores computer instructions for causing a computer device to execute the method(s) according to embodiments of this application. Specifically, a system or an apparatus that is equipped with a storage medium may be provided. The storage medium stores a software program code that implements functions of any of the foregoing embodiments, and a computer (or a CPU, or an MPU) of the system or the apparatus is enabled to read and execute the program code stored in the storage medium. In addition, an operating system and the like operating on the computer may also be caused to complete some or all actual operations through a program code-based instruction. The program code read from the storage medium may also be written into a memory that is disposed in an expansion board inserted in the computer, or may be written into a memory that is disposed in an expansion unit connected to the computer, and then the program code-based instruction causes a CPU or the like that is installed on the expansion board or the expansion unit to execute some or all actual operations, so as to implement the functions of any one of the foregoing embodiments. Embodiments of the storage medium for providing the program code include a floppy disk, a hard disk, a magneto-optical disk, an optical disk (such as a CD-ROM, a CD-R, a CD-RW, a DVD-ROM, a DVD-RAM, a DVD-RW, and a DVD+RW), a magnetic tape, a non-volatile storage card, and a ROM. In an embodiment, the program code may be downloaded from a computer of a blockchain server or a cloud through a communication network.

“Schematic” herein indicates “serving as an instance, an example, or description”. Any illustration or embodiment described as “schematic” herein should not be interpreted as a more preferred or advantageous technical solution. For brevity of the drawings, only parts related to this application are schematically shown in all the drawings, which do not represent an actual structure of a product. In addition, for brevity of the drawings and ease of understanding, for components with same structures or functions in some drawings, only one of the components is schematically shown or marked. “A” or “an” herein is not used to limit a quantity of relevant parts of this application as “only one”. “A” or “an” is not used to exclude a situation in which the quantity of the relevant parts of this application is “more than one”. “Up”, “down”, “front”, “back”, “left”, “right”, “inside” or “outside” and the like herein is used to indicate merely a relative positional relationship between the relevant parts, rather than limiting the absolute positions of those relevant parts.

The foregoing descriptions are merely embodiments of this application, which are not intended to limit the protection scope of this application. Any modification, equivalent replacement, or improvement made within the spirit and principle of this application shall be contained within the protection scope of this application.

1. A method for determining a temperature of a cooling liquid, comprising:
determining a first average temperature of a plurality of chips and a first average power of the plurality of chips in a blockchain server, wherein the blockchain server comprises a liquid cooling system, the liquid cooling system comprises a liquid cooling plate and the plurality of chips, the plurality of chips and the liquid cooling plate are in exchange of heat, and the cooling liquid is contained in the liquid cooling plate;
determining a thermal resistance coefficient of the liquid cooling system; and
determining a first temperature of the cooling liquid based on the first average temperature, the first average power and the thermal resistance coefficient.

2. The method according to claim 1, wherein determining the thermal resistance coefficient of the liquid cooling system comprises:
reading the thermal resistance coefficient of the liquid cooling system from a non-volatile memory of the blockchain server or a cloud storage device.

3. The method according to claim 2, further comprising:
determining a second average temperature of the plurality of chips and a second average power of the plurality of chips in a condition that the blockchain server has reached a pre-determined working condition in an ex-factory aging test of the blockchain server;
determining, based on a reading of a temperature sensor of a liquid supply system for providing the cooling liquid for the blockchain server in the ex-factory aging test, a second temperature of the cooling liquid in a condition that the blockchain server has reached the pre-determined working condition;
determining the thermal resistance coefficient based on the second average temperature, the second average power and the second temperature; and
storing the thermal resistance coefficient into the non-volatile memory of the blockchain server or the cloud storage device.

4. The method according to claim 1, wherein determining the thermal resistance coefficient of the liquid cooling system comprises:
obtaining a temperature of a chip board in a condition that the blockchain server has been powered on and the chip board containing the plurality of chips is not started;
starting the chip board;
determining a third average temperature of the plurality of chips and a third average power of the plurality of chips in a condition that power of the blockchain server has reached a pre-determined threshold value for a preset period; and
determining the thermal resistance coefficient of the liquid cooling system based on the third average temperature, the third average power and the temperature of the chip board.

5. The method according to claim 1, wherein
determining the first temperature of the cooling liquid based on the first average temperature, the first average power and the thermal resistance coefficient comprises:
determining T2,
wherein T2=T1−K*P; T1 is the first average temperature; T2 is the first temperature; K is the thermal resistance coefficient; and P is the first average power.

6. An apparatus for determining a temperature of a cooling liquid, comprising:
a first determining module, configured to determine a first average temperature of a plurality of chips and a first average power of the plurality of chips in a blockchain server, wherein the blockchain server comprises a liquid cooling system, the liquid cooling system comprises a liquid cooling plate and the plurality of chips, the plurality of chips and the liquid cooling plate are in exchange of heat, and the cooling liquid is contained in the liquid cooling plate;
a second determining module, configured to determine a thermal resistance coefficient of the liquid cooling system; and
a third determining module, configured to determine a first temperature of the cooling liquid based on the first average temperature, the first average power and the thermal resistance coefficient.

7. The apparatus according to claim 6, wherein
the second determining module is configured to read the thermal resistance coefficient of the liquid cooling system from a non-volatile memory of the blockchain server or a cloud storage device.

8. The apparatus according to claim 7, wherein
the second determining module is configured to determine a second average temperature of the plurality of chips and second average power of the plurality of chips in a condition that the blockchain server has reached a pre-determined working condition in an ex-factory aging test of the blockchain server; determine, based on a reading of a temperature sensor of a liquid supply system for providing the cooling liquid for the blockchain server in the ex-factory aging test, a second temperature of the cooling liquid in a condition that the blockchain server has reached the pre-determined working condition; determine the thermal resistance coefficient based on the second average temperature, the second average power and the second temperature; and storing the thermal resistance coefficient into the non-volatile memory of the blockchain server or the cloud storage device.

9. The apparatus according to claim 6, wherein
the second determining module is configured to: obtain a temperature of a chip board in a condition that the blockchain server has been powered on and the chip board containing the plurality of chips is not started; start the chip board; determine a third average temperature of the plurality of chips and a third average power of the plurality of chips in a condition that a power of the blockchain server has reached a pre-determined threshold value for a preset period; and
determine the thermal resistance coefficient of the liquid cooling system based on the third average temperature, the third average power and the temperature of the chip board.

10. The apparatus according to claim 6, wherein
the third determining module is configured to determine T2, wherein T2=T1−K*P; T1 is the first average temperature; T2 is the first temperature; K is the thermal resistance coefficient; and P is the first average power.

11. (canceled)

12. A blockchain server, comprising:
a liquid cooling plate, containing a cooling liquid;
a chip board, containing a plurality of chips, wherein the chip board and the liquid cooling plate are in exchange of heat; and
a control board, containing a memory and a processor,
wherein the chip board has a signal connection with the control board via a signal connection interface, and the chip board has an electrical connection with a power supply via a power supply connection interface, and
wherein, the memory stores an application program executable by the processor, to cause the processor to determine a temperature of the cooling liquid by:
determining a first average temperature of the plurality of chips in the blockchain server and a first average power of the plurality of chips, wherein the blockchain server comprises a liquid cooling system, the liquid cooling system comprises the liquid cooling plate and the plurality of chips;
determining a thermal resistance coefficient of the liquid cooling system; and
determining a first temperature of the cooling liquid based on the first average temperature, the first average power and the thermal resistance coefficient.

13. (canceled)

14. The blockchain server according to claim 11, wherein determining the thermal resistance coefficient of the liquid cooling system comprises:
reading the thermal resistance coefficient of the liquid cooling system from a non-volatile memory of the blockchain server or a cloud storage device.

15. The blockchain server according to claim 12, wherein the memory stores an application program executable by the processor, to cause the processor to further:
determine a second average temperature of the plurality of chips and a second average power of the plurality of chips in a condition that the blockchain server has reached a pre-determined working condition in an ex-factory aging test of the blockchain server;
determine, based on a reading of a temperature sensor of a liquid supply system for providing the cooling liquid for the blockchain server in the ex-factory aging test, a second temperature of the cooling liquid in a condition that the blockchain server has reached the pre-determined working condition;
determine the thermal resistance coefficient based on the second average temperature, the second average power and the second temperature; and
store the thermal resistance coefficient into the non-volatile memory of the blockchain server or the cloud storage device.

16. The blockchain server according to claim 11, wherein determining the thermal resistance coefficient of the liquid cooling system comprises:
obtaining a temperature of the chip board in a condition that the blockchain server has been powered on and the chip board containing the plurality of chips is not started;
starting the chip board;
determining a third average temperature of the plurality of chips and a third average power of the plurality of chips in a condition that power of the blockchain server has reached a pre-determined threshold value for a preset period; and
determining the thermal resistance coefficient of the liquid cooling system based on the third average temperature, the third average power and the temperature of the chip board.

17. The blockchain server according to claim 11, wherein
determining the first temperature of the cooling liquid based on the first average temperature, the first average power and the thermal resistance coefficient comprises:
determining T₂, wherein T₂=T₁−K*P; T₁ is the first average temperature; T₂ is the first temperature; K is the thermal resistance coefficient; and P is the first average power.
